(19) United States
(12) Patent Application Publication
(10) Pub. No.: US 2025/0218961 A1
(43) Pub. Date: Jul. 3, 2025

(54) METHODS AND APPARATUS TO FACILITATE SEMICONDUCTOR DEVICE ALIGNMENT IN AN INTEGRATED CIRCUIT PACKAGE

(71) Applicant: Intel Corporation, Santa Clara, CA (US)

(72) Inventors: Tolga Acikalin, San Jose, CA (US); Benjamin Duong, Phoenix, AZ (US); Soham Agarwal, Chandler, AZ (US); Jeremy Ecton, Gilbert, AZ (US); Kari Hernandez, Phoenix, AZ (US); Brandon Christian Marin, Gilbert, AZ (US); Pratyush Mishra, Tempe, AZ (US); Pratyasha Mohapatra, Hillsboro, OR (US); Srinivas Venkata Ramanuja Pietambaram, Chandler, AZ (US); Marcel Said, Beaverton, OR (US)

(21) Appl. No.: 18/399,212

(22) Filed: Dec. 28, 2023

(51) Int. Cl. H01L 23/538; H01L 21/52; H01L 21/56; H01L 23/00; H01L 25/065

(52) U.S. Cl. CPC H01L 23/5386; H01L 21/52; H01L 21/568; H01L 23/5383; H10D 1/68; H01L 24/14; H01L 24/16; H01L 25/0655; H01L 2224/14177; H01L 2224/16227

(57) ABSTRACT

An apparatus includes a package substrate comprising a core having a first surface along a first plane and a second surface along a second plane, a semiconductor device disposed within an opening in the core, the semiconductor device having a third surface along a third plane and a fourth surface along a fourth plane, the third plane substantially parallel to the first plane, a first dielectric material disposed on the first surface of the core, the first dielectric material extends into the opening to fill a first gap between a wall of the opening and a lateral surface of the semiconductor device, and a second dielectric material disposed on the second surface of the core, the second dielectric material extends into the opening to fill a second gap between the second plane and the fourth plane.

### FIELD OF THE DISCLOSURE

This disclosure relates generally to semiconductor manufacturing and, more particularly, to methods and apparatus to facilitate semiconductor device alignment in an integrated circuit package.

### BACKGROUND

Semiconductor manufacturing is a process for creating integrated circuits, central processing units (CPUs), and many other kinds of electronic components. Semiconductor manufacturing includes precision control and placement of components within integrated circuit (IC) packages.

### BRIEF DESCRIPTION OF THE DRAWINGS

FIG. 1 illustrates an example integrated circuit (IC) package constructed in accordance with teachings disclosed herein.

FIG. 2 illustrates a first example stage of a build process to construct the IC package of FIG. 1.

FIG. 3 illustrates a second example stage of the build process to construct the IC package of FIG. 1.

FIG. 4 illustrates a third example stage of the build process to construct the IC package of FIG. 1.

FIG. 5 illustrates a fourth example stage of the build process to construct the IC package of FIG. 1.

FIG. 6 illustrates a fifth example stage of the build process to construct the IC package of FIG. 1.

FIG. 7 illustrates a first alternate build configuration to the first example stage of FIG. 2.

FIG. 8 illustrates a first alternate build configuration to the fifth example stage of FIG. 6.

FIG. 9 illustrates a second alternate build configuration to the first example stage of FIG. 2.

FIG. 10 illustrates a second alternate build configuration to the fifth example stage of FIG. 6

FIG. 11 is a flowchart representative of example operations that can be performed to manufacture the IC package of FIG. 1 according to example disclosed herein.

FIG. 12 is a top view of a wafer including dies that may be included in an IC package constructed in accordance with teachings disclosed herein.

FIG. 13 is a cross-sectional side view of an IC device that may be included in an IC package constructed in accordance with teachings disclosed herein.

FIG. 14 is a cross-sectional side view of an IC device assembly that may include an IC package constructed in accordance with teachings disclosed herein.

FIG. 15 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

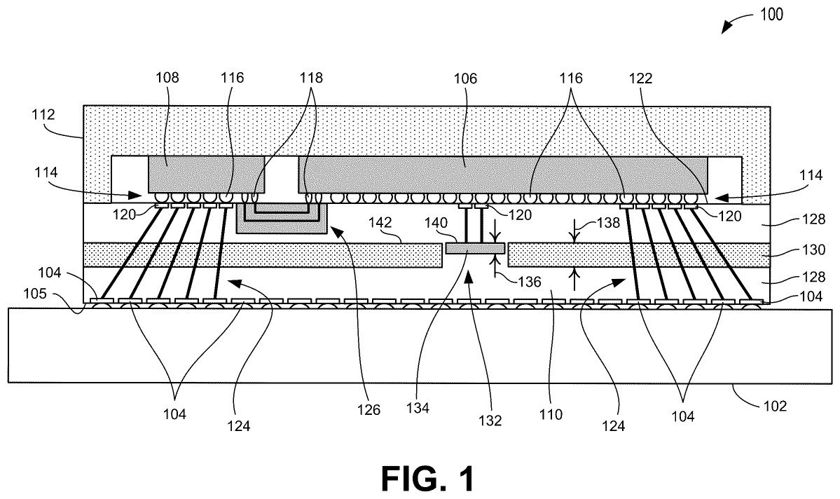

FIG. 1 illustrates an example integrated circuit (IC) package 100 constructed in accordance with teachings disclosed herein. In the illustrated example, the IC package 100 is electrically coupled to a circuit board 102 via an array of contact pads or lands 104 on a mounting surface 105 (e.g., a bottom surface) of the package. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. Thus, the package substrate 110 is an example means for supporting a semiconductor die. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the pads 104 on the bottom (external) surface 105 of the substrate 110 (e.g., a surface opposite the inner surface 122) via internal interconnects 124 within the substrate 110. As a result, there is a continuous electrical signal path between the interconnects 114 of the dies 106, 108 and the pads 104 mounted to the circuit board 102 that pass through the contact pads 120 and the interconnects 124 provided therebetween.

As used herein, the bridge bumps 118 are bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

For purposes of illustration, the internal interconnects 124 are shown as straight lines extending directly between the pads 104 on the bottom surface 105 and the contact pads on the inner surface 122. However, in some examples, the internal interconnects 124 are defined by traces or routing in separate conductive (e.g., metal) layers within build-up regions 128 on one or both sides of a substrate core 130 in the package substrate 110. In such examples, the build-up regions 128 include dielectric layers to separate the different conductive layers. In such examples, the traces or routing in the different conductive layers are electrically coupled (to define the complete electrical path of the internal interconnects 124) by conductive (e.g., metal) vias extending between the different conductive layers. Further, in some examples, the internal interconnects 124 include vias that extend through the substrate core 130.

In some examples, the substrate core 130 is an organic substrate or core (e.g., an epoxy-based prepreg layer). In other examples, the substrate core 130 is a glass substrate or core. In some examples, glass substrates (e.g., the glass core 130) includes quartz, fused silica, and/or borosilicate glass. In some examples, glass substrates (e.g., the glass core 130) includes at least 20% (by weight) of each of silicon (Si) and oxygen (O). In other examples, glass substrates (e.g., the glass core 130) includes greater amounts of at least one of silicon or oxygen (e.g., at least 25 wt %, at least 30 wt %, at least 35 wt %, at least 40 wt %, etc.). In some examples, glass substrates (e.g., the glass core 130) includes at least 5% (by weight) of aluminum (Al). In accordance with the present disclosure, glass substrates (e.g., the glass core 130) include at least one glass layer and do not include epoxy and does not include glass fibers (e.g., does not include an epoxy-based prepreg layer with glass cloth). In some examples, glass substrates (e.g., the glass core 130) correspond to a single piece of glass that extends the full height/thickness of the core. In some examples, the glass core 130 has a rectangular shape that is substantially coextensive, in plan view, with the layers above and below the core (e.g., substantially coextensive with the build-up regions 128). The substrate core 130, whether an organic core or a glass core, provides stiffness and mechanical support or strength for the package substrate 110 and the rest of the package 100. Thus, the substrate core 130 is an example means for strengthening the package substrate. In some examples, the thickness of the core 130 is driven by the size (e.g., footprint) of the package 100. For example, in some instances, larger packages 100 include a substrate 110 with a larger (e.g., thicker) core 130 as compared with smaller packages 100 where the core does not need to be as thick.

As shown in the illustrated example, the substrate core 130 includes a cavity 132 in which a semiconductor device 134 is embedded. In some examples, the semiconductor device 134 is a passive semiconductor die (e.g., a die that does not include transistors). In this example, the semiconductor device 134 is a deep trench capacitor die (also referred to herein as a deep trench capacitor for short). In some such examples, the deep trench capacitor is used to enable efficient power delivery to a fully integrated voltage regulator within the first die 106 in the IC package 100. In other examples, other types of semiconductor devices can be embedded within the cavity 132 of the substrate core 130 in addition to or instead of a deep trench capacitor. In some examples, more than one semiconductor device 134 can be embedded within the cavity 132 of the substrate core 130. In some examples, the substrate core 130 can include multiple cavities each containing one or more separate semiconductor devices 134.

As noted above, in this example, the semiconductor device 134 is a deep trench capacitor and will be referred to as such going forward. As shown in the illustrated example, the deep trench capacitor 134 is electrically coupled to the first die 106. In some examples, the deep trench capacitor 134 is positioned in close proximity to the first die 106 (e.g., within the substrate core 130 rather than spaced farther away like land-side capacitors) to reduce inductance and parasitic effects, thereby increasing the effectiveness of the deep trench capacitor 134 (and/or achieving a given capacitance with a smaller sized capacitor). However, a challenge with embedding a deep trench capacitor 134 within a core 130 of a substrate arises from the thickness mismatch between the deep trench capacitor 134 and the core 130. In this example, the deep trench capacitor 134 is constructed through wafer-level processing from a semiconductor (e.g., silicon) wafer. Due to the nature of such wafer-level processing, the deep trench capacitor 134 has a thickness 136 limited to less than or equal to approximately 800 micrometers (μm) or less (e.g., less than or equal to approximately 700 μm, less than or equal to approximately 650 μm, less than or equal to approximately 600 μm, etc.). By contrast, the substrate core 130 can be significantly thicker, especially for larger packages as noted above. For instance, in some examples, the core 130 has a thickness 138 that is at least 20% greater than the thickness 136 of the deep trench capacitor 134 or more (e.g., at least 25% greater, at least 30% greater, at least 50% greater, at least 75% greater, at least twice as great, etc.). More specifically, in some examples, the thickness 138 of the core 130 is greater than approximately 800 μm or more (e.g., greater than or equal to approximately 1 millimeter (mm) (e.g., 1000 μm), greater than or equal to approximately 1.2 mm, greater than or equal to approximately 1.4 mm, greater than or equal to approximately 1.5 mm, etc.). Thus, as shown in FIG. 1, the thickness 136 of the deep trench capacitor 134 is less than the thickness 138 of the core 130.

The mismatch between the thicknesses 136, 138 of the deep trench capacitor 134 and the core 130 presents challenges in positioning the deep trench capacitor 134 within the cavity 132 of the core 130. Specifically, the relatively small size of the deep trench capacitor 134 can result in misalignments in any of the x, y, and z axes and/or rotational shifting or tilting because of the difficulty in securing the deep trench capacitor in place. In particular, the use of adhesives and/or an encapsulant to hold the deep trench capacitor 134 in place can be difficult because of the large space within the cavity 132 that needs to be filled which can take time to set or cure during which the deep trench capacitor 134 may shift, rotate, or otherwise move. As a result, a contact surface 140 of the deep trench capacitor 134 (e.g., a surface containing contacts with which the deep trench capacitor 134 is electrically coupled to (and facing towards) the first die 106) may not be aligned (e.g., flush) with a corresponding surface 142 (also facing towards the first die 106) of the substrate core 130. Such misalignment can negatively affect the ability of the deep trench capacitor 134 to electrically connect with the interconnects within the build-up region 128 above the core 130. Furthermore, the non-homogeneity of materials within the cavity 132 (e.g., a deep trench capacitor 134 and a relatively large volume of adhesive and/or encapsulant) can create processing challenges downstream and/or increase risks of warpage and/or mechanical stress in the package substrate 110.

Examples disclosed herein overcome the above challenges by providing a spacer, pedestal, or other structure to fill much of the space within the cavity 132 and support the deep trench capacitor at a suitable height and at a suitable location relative to the substrate core 130. Examples disclosed herein allow for the removal of the spacer, pedestal, or other structure after placing/aligning the deep trench capacitor 134 relative to the substrate core 130. That is, in some examples, the spacer or pedestal is a temporary structure used during the fabrication of an integrated circuit package that is subsequently removed once the deep trench capacitor 134 is secured in place by other means (e.g., an adhesive or mold material that at least partially surrounds the deep trench capacitor 134).

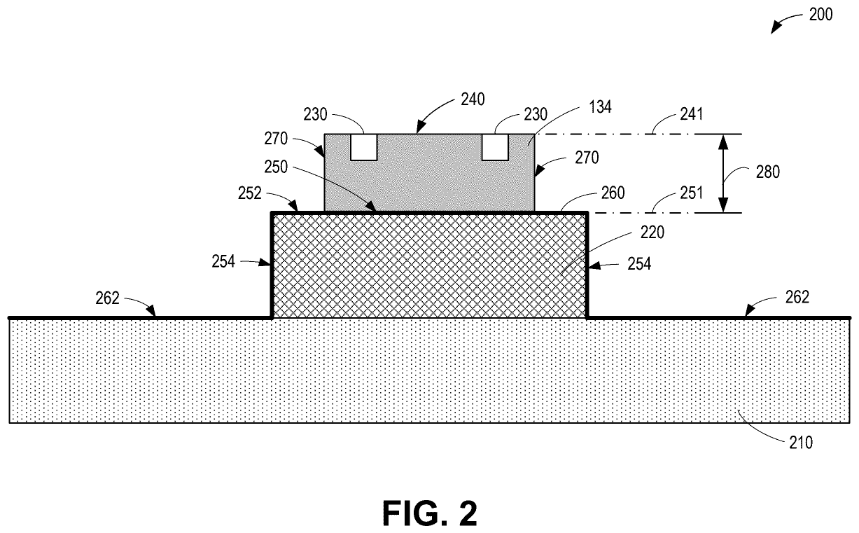

FIG. 2 illustrates a first example stage 200 of a build process to construct the IC package 100 of FIG. 1. The first example stage 200 includes the deep trench capacitor 134 of FIG. 1 positioned on a carrier 210 with a pedestal 220 (e.g., a spacer, a platform, etc.). In the example of FIG. 2, the pedestal 220 is on the carrier 210 and the deep trench capacitor 134 interfaces with the pedestal 220. In some examples disclosed herein, the pedestal 220 is an integral extension of or protrusion on the carrier 210 (e.g., the pedestal 220 is integrally coupled to the carrier 210). In other examples, the pedestal 220 is distinct from the carrier and attached thereto (e.g., via an adhesive).

In examples disclosed herein, the carrier 210 is made of glass, silicon (Si), metal (e.g., aluminum, steel, etc.), ceramic, or any combination or derivative thereof. In some examples, the pedestal 220 is made of the same material as the carrier 210. In other examples, the pedestal 220 is made of a different material than the carrier 210. The pedestal 220 is designed/sized so as to support the deep trench capacitor 134 to facilitate alignment of the deep trench capacitor 134 with other components in the IC package 100 of FIG. 1. More particularly, as disclosed herein, the pedestal 220 facilitates alignment of the deep trench capacitor 134 with other components within the IC package 100 to reduce or remove misalignments caused by manual or imprecise placement of semiconductor devices within the IC package 100. Specifically, as discussed further below, the deep trench capacitor 134 can be placed on or supported on the pedestal 220 that is dimensioned (e.g., has a thickness) that positions a first semiconductor device surface 240 (e.g., an outward facing) of the deep trench capacitor 134 in alignment with a corresponding (e.g., adjacent) surface of the substrate core 130.

The deep trench capacitor 134 of FIG. 2 includes one or more contact pad(s) 230 on the first semiconductor device surface 240. In some examples, the contact pad(s) 230 are included on the deep trench capacitor 134 to enable an electrical connection between the first die 106 (or the second die 108 in some examples) and the deep trench capacitor 134 (as discussed in connection with FIG. 1). In the illustrated example of FIG. 2, the contact pad(s) 230 are embedded within the deep trench capacitor 134 so that the outward facing surfaces of the contact pad(s) are substantially flush with the first semiconductor device surface 240. In some examples, the contact pad(s) 230 are recessed relative to the first semiconductor device surface 240. In some examples, the contact pad(s) 230 protrude outward from the first semiconductor device surface 240. In the example of FIG. 2, the deep trench capacitor 134 includes two contact pad(s) 230, but it should be understood that the deep trench capacitor 134 can include any suitable number of the contact pads 230.

The deep trench capacitor 134 of FIG. 2 includes a second semiconductor device surface 250 that is opposite the first semiconductor device surface 240. The first semiconductor device surface 240 includes the contact pad(s) 230 and faces the dies 106, 108 (e.g., once the IC package 100 is fully assembled). The first semiconductor device surface 240 defines a first semiconductor device plane 241.

The second semiconductor device surface 250 faces the pedestal 220 (e.g., during assembly and before the subsequent removal of the pedestal 220). The second semiconductor device surface 250 defines a second semiconductor device plane 251. In some examples, the first semiconductor device plane 241 is substantially parallel to the second semiconductor device plane 251. As used herein, substantially parallel means within 5 degrees of exactly parallel.

The pedestal 220 includes a first pedestal surface 252 and a side pedestal surface 254. In the example of FIG. 2, the pedestal 220 includes two side pedestal surfaces 254, each surface opposite each other. The second semiconductor device surface 250 interfaces with the first pedestal surface 252. In some examples, the first pedestal surface 252 extends laterally beyond the second semiconductor device surface 250. In other examples, the first pedestal surface 252 extends laterally up to or less than the boundary or perimeter of the second semiconductor device surface 252.

In some examples, the second semiconductor device surface 250 is coupled to the pedestal 220 via a debonding film 260 to enable the subsequent separation of the pedestal 220 and the deep trench capacitor 134. The debonding film 260 can include, but is not limited to, epoxy resins, dry films, benzocyclobutene (BCB), polyimide, and UV-curable compounds. In some examples, the debonding film 260 is positioned on the deep trench capacitor 134 or any additional structure via spin coating and/or deposited by chemical vapor disposition (CVD) or physical vapor disposition (PVD). In some examples, the debonding film 260 is positioned along an entire exposed surface of the carrier 210 and the pedestal 220 at the same time. For example, the debonding film 260 is placed along the first pedestal surface 252, the side pedestal surfaces 254, and a top carrier surface 262. In other examples, the debonding film 260 is positioned to cover the component (e.g., the deep trench capacitor 134) being positioned on the carrier 210 and/or the pedestal 220. In such an example, the debonding film 260 would be positioned to a width of the second semiconductor device surface 250 on the first pedestal surface 252.

The deep trench capacitor 134 of FIG. 2 also includes a lateral surface 270. As shown in the example of FIG. 2, the deep trench capacitor 134 includes two lateral surfaces 270 opposite each other. The lateral surface 270 is substantially perpendicular to the first semiconductor device plane 241 and/or the second semiconductor device plane 251. As used herein, substantially perpendicular means within 5 degrees of exactly perpendicular.

The deep trench capacitor 134 has a capacitor (cap) thickness 280 defined by the first semiconductor device surface 240 and the second semiconductor device surface 250.

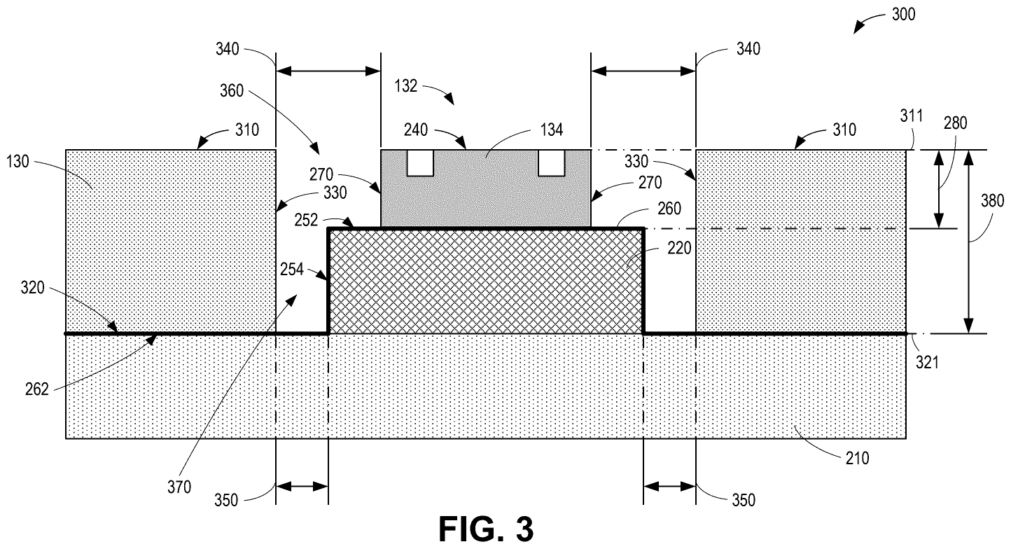

FIG. 3 illustrates a second example stage 300 of the build process to construct the IC package 100 of FIG. 1. In the example of FIG. 3, the substrate core 130 is positioned on the carrier 210 such that the pedestal 220 and the deep trench capacitor 134 are positioned within the cavity 132 of the substrate core 130.

The substrate core 130 includes a first core surface 310 and a second core surface 320. The first core surface 310 faces the dies 106, 108 (e.g., once the IC package 100 is fully assembled). The first core surface 310 defines a first core plane 311 that is substantially parallel to the first semiconductor device plane 241. In some examples, the first core surface 310 is substantially flush with the first semiconductor device surface 240. As used herein, substantially flush means within 5 degrees of angular offset and/or within 25 micrometers of misalignment.

In some examples, the pedestal 220 is dimensioned/sized to place the first core surface 310 in substantial coplanar alignment with the first semiconductor device surface 240. As used herein, substantial coplanar alignment means substantially parallel and within 25 micrometers of linear offset or less (e.g., within 20 micrometers, within 15 micrometers, within 10 micrometers, within 5 micrometers, etc.).

The second core surface 320 faces the carrier 210. The second core surface 320 defines a second core plane 321 that is substantially parallel to the second semiconductor device plane 251. In some examples, the second core surface 320 is coupled to the carrier 210 via the debonding film 260. In some examples, different portions of the debonding film 260 are deposited on the carrier 210 at different times correspond to when different components are positioned on the carrier 210. For instance, in some examples, a first portion of the debonding film 260 is added to the first pedestal surface 252 when the deep trench capacitor 134 is positioned and adhered to the pedestal 220 and a second portion of the debonding film 260 is added to the second core surface when the substrate core 130 is positioned and adhered to the carrier 210. In some such examples, the second portion of the debonding film 260 is limited to a width, footprint, or area of the substrate core 130 along the first carrier surface 262. In some examples, a final portion of the debonding film 260 can then be placed on a remaining surface of the carrier 210 and/or the pedestal 220 (e.g., from an edge of the substrate core 130 along the first carrier surface 262, along the side pedestal surface 254, and along the first pedestal surface 252 up to an edge of the deep trench capacitor 134). Therefore, in some examples, the debonding film 260 can be positioned in three stages: a first debonding film stage corresponding to positioning the deep trench capacitor 134, a second debonding film stage corresponding to positioning the substrate core 130, and a third debonding film stage corresponding to positioning the debonding film 260 on the remaining surfaces of the carrier 210 and the pedestal 220. In the above example, the deep trench capacitor 134 is positioned on the pedestal 220 before the substrate core 130 is positioned on the carrier 210. However, in other examples, the substrate core 130 can be positioned on the carrier 210 before the deep trench capacitor 134 is positioned on the pedestal 220.

In the example of FIG. 3, the substrate core 130 includes a wall 330 corresponding to the cavity 132. The wall 330 faces the pedestal 220 and the lateral surface 270 of the deep trench capacitor 134.

In some examples, corresponding to the second example stage 300, the IC package 100 includes a first distance 340 between the lateral surface 270 and the wall 330 and a second distance 350 between the wall 330 and the side pedestal surface 254. In some examples, the first distance 340 and the second distance 350 are the same. In the example of FIG. 3, the first distance 340 and the second distance 350 are different such that the first distance 340 is larger than the second distance 350. In some examples, the pedestal 220 and/or the deep trench capacitor 134 is not centered within the cavity 132 such that the first and second distances 340, 350 differ on different sides of the pedestal 220 and/or the deep trench capacitor 134.

The first distance 340 defines a first gap 360. The first gap 360 includes a portion of the IC package 100 from the wall 330 of the substrate core 130 to the lateral surface 270 of the deep trench capacitor 134 in a horizontal direction, and from the first semiconductor device plane 241 (or the first core plane 311) to the second semiconductor device plane 251 (or the first pedestal surface 252) in a vertical direction.

The second distance 350 defines a second gap 370. The second gap 370 includes a portion of the IC package 100 from the wall 330 of the substrate core 130 to the side pedestal surface 254 in the horizontal direction, and from the second semiconductor device plane 251 (or the first pedestal surface 252) to the second core plane 321 in the vertical direction.

The substrate core 130 has a core thickness 380 defined by the first core surface 310 and the second core surface 320. In some examples, the core thickness 380 is greater than the cap thickness 280.

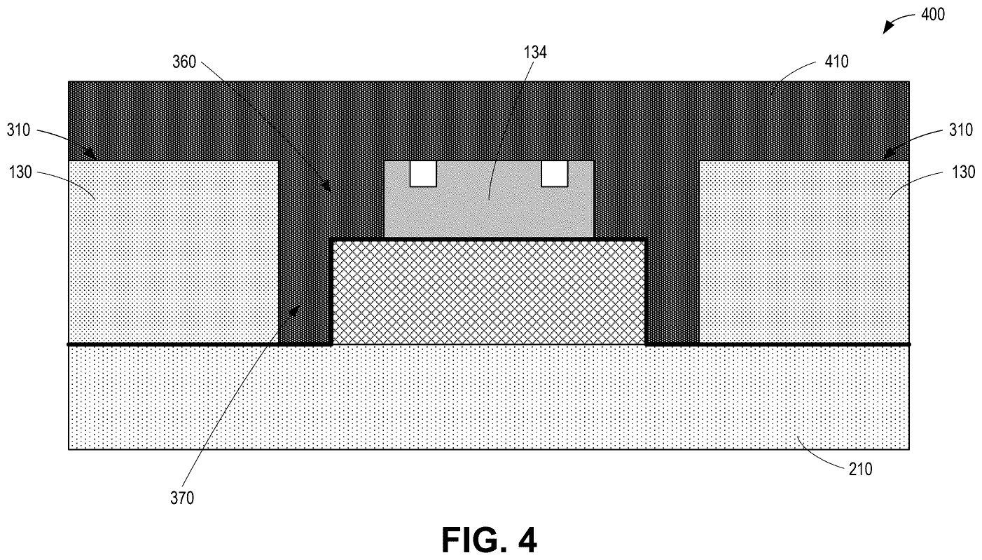

FIG. 4 illustrates a third example stage 400 of the build process to construct the IC package 100 of FIG. 1. In the third example stage, a first dielectric material 410 is disposed on the first surface 310 of the substrate core 130.

In the example of FIG. 4, the first dielectric material 410 is made of a mold compound (encapsulant), organic epoxy buildup film, a photoimageable dielectric (PID), silica (SiO2), hafnium silicate (HfSiO4), zirconium silicate, or any other suitable dielectric material for encasing semiconductor components.

The first dielectric material 410 is disposed to fill the first gap 360 and the second gap 370. In some examples, the first dielectric material 410 does not completely fill the second gap 370 but partially fills the second gap 370. In some examples, the first dielectric material does not extend into the second gap (e.g., the first dielectric material fills the first gap 360 without filling the second gap 370). In some examples, the first dielectric material 410 does not completely fill the first gap 360 but partially fills the first gap 370. In the illustrated example of FIG. 4, the first dielectric material 410 has a first lateral thickness at the first gap 360 equal to the first distance 340. The first dielectric material 410 has a second lateral thickness at the second gap 370 equal to the second distance 350. In some examples, the first dielectric material 410 is disposed all at once (e.g., continual). In other examples, the first dielectric material 410 is disposed in intervals to form layers (e.g., disposing a first layer, waiting for the first layer to dry/solidify, and then disposing a second/subsequent layer). The first dielectric material 410 is disposed to encase the substrate core 130 and/or the deep trench capacitor 134. In some examples, the first dielectric material 410 also defines a first dielectric layer in one of the build-up regions 128 on a first side of the substrate core 130.

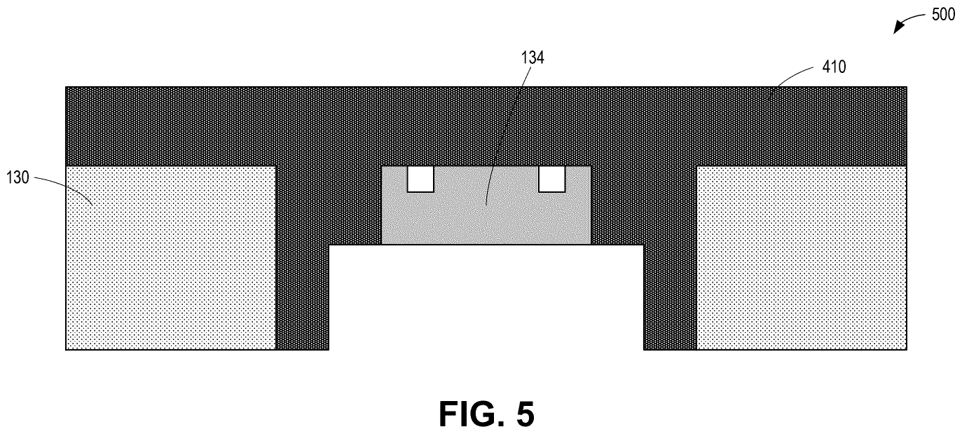

FIG. 5 illustrates a fourth example stage 500 of the build process to construct the IC package 100 of FIG. 1. In the example of FIG. 5, the pedestal 220 and the carrier 210 are removed from the substrate core 130 and the deep trench capacitor 134. In this example, the first dielectric material 410 retains the position of the deep trench capacitor 134 relative to the substrate core 130. Thus, in some examples, the carrier 210 and the pedestal 220 are not removed until the first dielectric material 410 has set, hardened, or cured.

In some examples, where the debonding film 260 is used to bond the deep trench capacitor 134 to the pedestal 220 and the substrate core 130 to the carrier 210, a debonding process is required to remove the debonding film to facilitate removal of the pedestal 220 and the carrier 210. Examples of debonding processes that can be used herein to remove the debonding film 260 include, but are not limited to, a heat source, a laser source, an ultraviolet light source, or through the application of a solvent that reacts with the debonding film to release the film. In some examples, where the debonding film 260 is not used, the debonding process is not required to remove the pedestal 220 and the carrier 210.

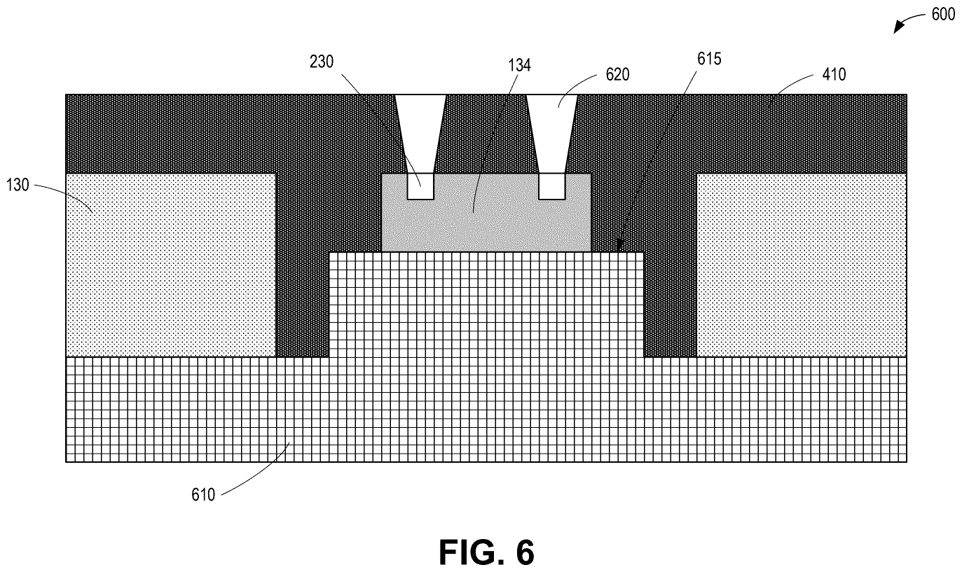

FIG. 6 illustrates a fifth example stage 600 of the build process to construct the IC package 100 of FIG. 1. In the example of FIG. 6, a second dielectric material 610 is disposed in the space previously occupied by the carrier 210 and the pedestal 220 to fill the remaining open space within the cavity. Further, in some examples, the second dielectric material 610 also defined a first dielectric layer in the build-up region 128 on the second side of the substrate core 130 (opposite the first build-up region 128 defined by the first dielectric material 410. The second dielectric material 610 can comprise any of the materials listed above with respect to the first dielectric material 410. In some examples, the second dielectric material 610 is the same material as the first dielectric material 410. In other examples, the second dielectric material 610 is a different material than the first dielectric material 410.

In the example of FIG. 6, the first dielectric material 410 and the second dielectric material 610 are in contact at an interface 615 corresponding to the location of the surfaces of the carrier 210 and the pedestal 220 prior to their removal. In some examples, at least a portion of the interface 615 between the first dielectric material 410 and the second dielectric material 610 extends transverse to the first core surface 310 and the second core surface 320. In some examples, the interface is unobservable. In some examples, at least a portion of the interface 615 is substantially coplanar with the second semiconductor device surface 250 of the deep trench capacitor 134.

In some examples, one or more conductive (e.g., metal) vias 620 are positioned to extend through the first dielectric material 410 to contact the contact pad(s) 230 on the deep trench capacitor 134. The conductive vias 620 facilitate connection of deep trench capacitor 134 to the internal interconnects 124 within the build-up regions 128 to enable electrically coupling with the contact pads 120 and the first die 106, as shown in FIG. 1. Although the conductive vias 620 are disclosed in connection with FIG. 6 in this example, the conductive vias 620 can be added in connection with the example stages of fabrication represented in FIGS. 4 and/or 5 as well (e.g., the third example stage 400 and/or the fourth example stage 500).

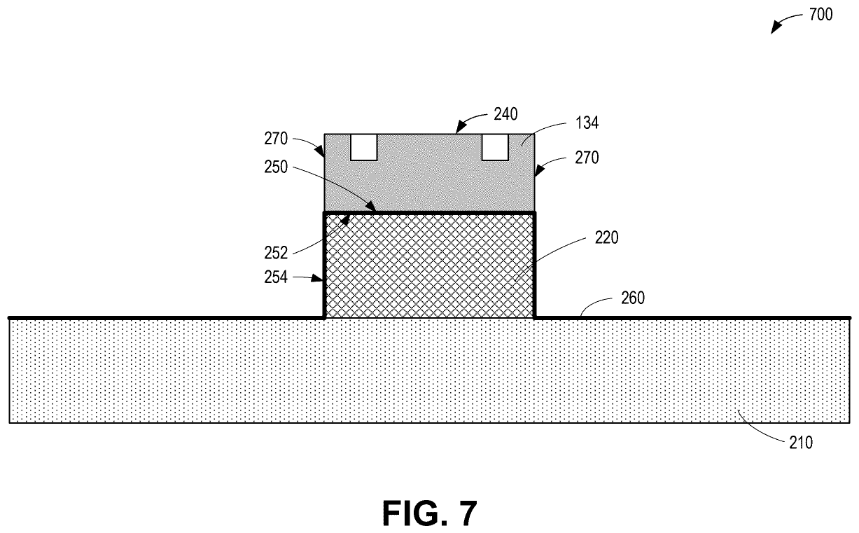

FIG. 7 illustrates a first alternate build configuration 700 to the first example stage 200 of FIG. 2. In the example of FIG. 7, the pedestal 220 includes the first pedestal surface 252 and the side pedestal surfaces 254. The deep trench capacitor 134 includes the first semiconductor device surface 240, the second semiconductor device surface 250, and the lateral surface 270.

As illustrated in FIG. 7, the side pedestal surfaces 254 are aligned with the lateral surfaces 270. Therefore, a width of the pedestal 220 (e.g., a distance of the first pedestal surface 252 up to the side pedestal surfaces 254) is substantially equal to (e.g., within 50 μm of equal) a width of the deep trench capacitor 134 (e.g., a distance of the first or second semiconductor device surface 240, 250 up to the lateral surfaces 270).

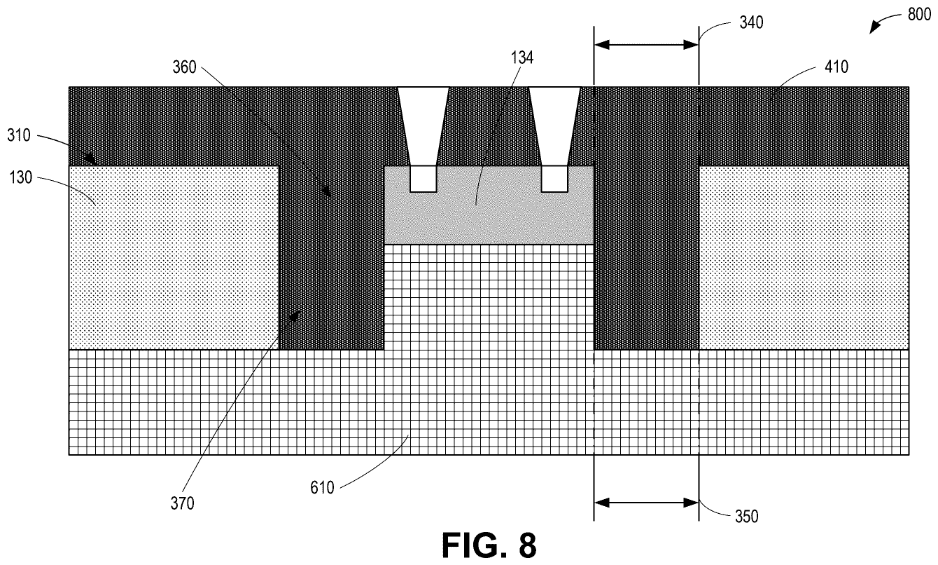

FIG. 8 illustrates a first alternate build configuration 800 to the fifth example stage 600 of FIG. 6. In the example of FIG. 8, the first dielectric material 410 is disposed on the first core surface 310 and fills the first gap 360 and the second gap 370.

As illustrated in the example of FIG. 8, the first gap 360 is relatively equal to the second gap 370. In such an example, the first distance 340 and the second distance 350 are substantially equal to each other.

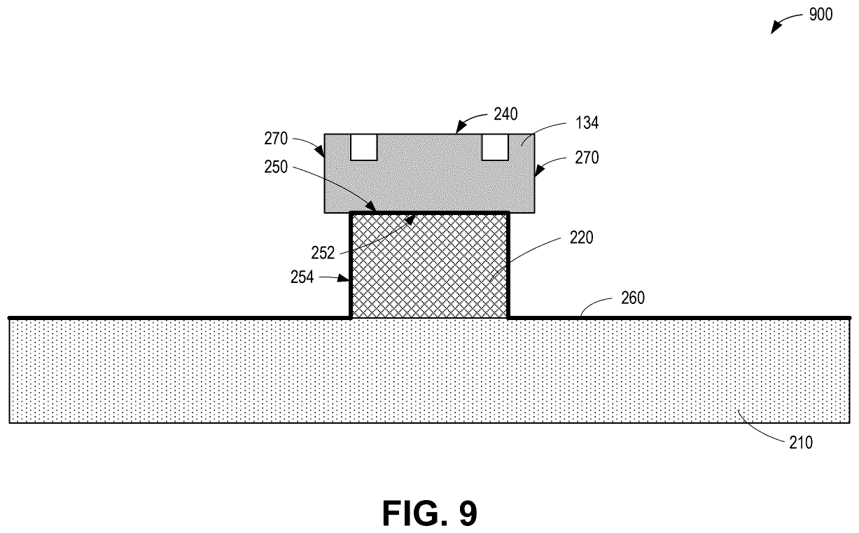

FIG. 9 illustrates a second alternate build configuration 900 to the first example stage 200 of FIG. 2. In the example of FIG. 9, the pedestal 220 includes the first pedestal surface 252 and the side pedestal surfaces 254. The deep trench capacitor 134 includes the first semiconductor device surface 240, the second semiconductor device surface 250, and the lateral surface 270.

As illustrated in FIG. 9, the lateral surfaces 270 of the deep trench capacitor 134 extend laterally beyond the side pedestal surfaces 254. Therefore, the width of the pedestal 220 is less than the width of the deep trench capacitor 134.

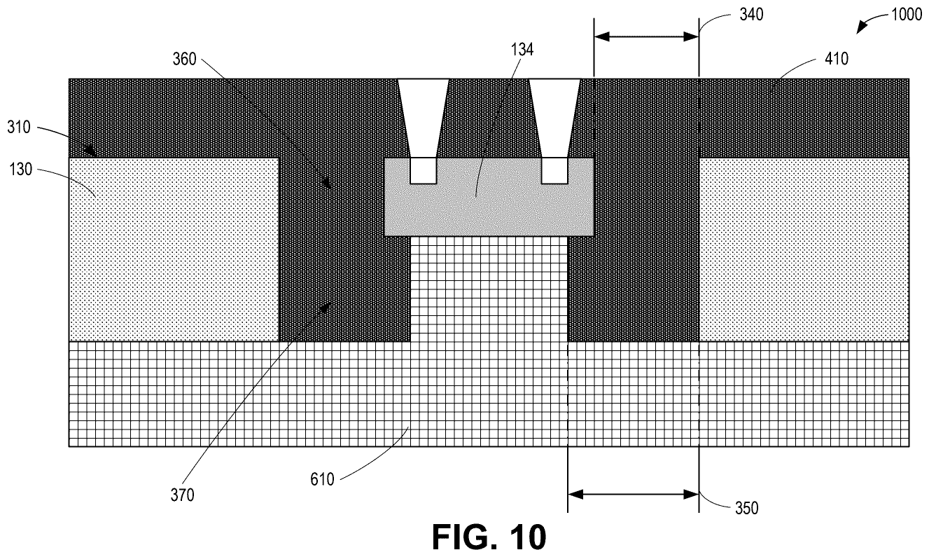

FIG. 10 illustrates a second alternate build configuration 1000 to the fifth example stage 600 of FIG. 6. In the example of FIG. 10, the first dielectric material 410 is disposed on the first core surface 310 and fills the first gap 360 and the second gap 370.

As illustrated in the example of FIG. 10, the first gap 360 is smaller than the second gap 370. In such an example, the first distance 340 is less than the second distance 350.

The examples shown in FIGS. 2-6, in FIGS. 7 and 8, and in FIGS. 9 and 10 can be interchangeably used herein according to the teachings of this disclosure. FIGS. 2-10 illustrate alternate configurations that may be necessary based on sizing or operability requirements of the build-up regions 128, the substrate core 130, or any other component within the IC package 100 of FIG. 1.

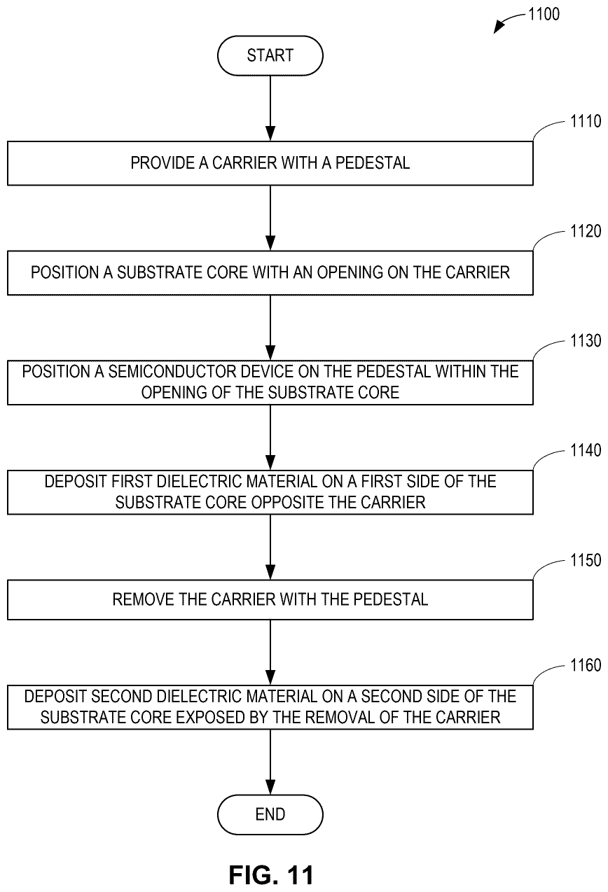

While an example manner of manufacturing the example IC package 100 of FIG. 1 is illustrated in FIG. 11, one or more of the elements, processes, and/or devices illustrated in FIG. 11 may be combined, divided, re-arranged, omitted, eliminated, and/or implemented in any other way.

FIG. 11 is a flowchart representative of example operations 1100 that can be performed to manufacture the IC package 100 of FIG. 1 according to examples disclosed herein. The example operations 1100 of FIG. 11 begin at block 1110 at which the carrier 210 and the pedestal 220 are provided. In some examples, the carrier 210 and the pedestal 220 are manufactured together and provided as a single piece to be used to align a semiconductor device (e.g., the deep trench capacitor 134).

Once the carrier 210 and pedestal 220 have been provided, the substrate core 130 is positioned on the carrier 210. (Block 1120). In some examples, the substrate core 130 is positioned first since the substrate core 130 includes an opening/gap (e.g., the cavity 132) within which to position the semiconductor device. In some examples, the debonding film 260 is placed at this stage to bond the substrate core 130 to the carrier 210.

Once the substrate core 130 is positioned on the carrier 210, the semiconductor device is positioned on the pedestal 220 within the opening/gap in the substrate core 130. (Block 1130). In some examples, the semiconductor device is positioned prior to the substrate core 130 being positioned. In some examples, the debonding film 260 is placed at this stage to bond the semiconductor device to the pedestal 220.

Once the substrate core 130 and the semiconductor device have been positioned on the carrier 210 and the pedestal 220 respectively, the first dielectric material 410 is disposed on a first side of the substrate core 130 (e.g., the first core surface 310) opposite the carrier 210. (Block 1140). In some examples, the first dielectric material 410 is disposed to encase the substrate core 130 and the semiconductor device. In some examples, the first dielectric material 410 encases the semiconductor device without encasing the substrate core 130. In some examples, the first dielectric material 410 is disposed to serve as a dielectric layer in a build-up region 128 adjacent to the substrate core 130. As disclosed herein, the first dielectric material 410 fills some or all of the first gap 360 and some or all of the second gap 370.

Once the first dielectric material 410 is disposed, the carrier 210 and the pedestal 220 are removed. (Block 1150). In some examples, when the debonding film 260 is used, a debonding process is required to remove the debonding film 260 to allow the removal of the carrier 210 and the pedestal 220. As disclosed above, examples of debonding processes include a heat source or an ultraviolet light source.

Once the carrier 210 and the pedestal 220 are removed, the second dielectric material 610 is disposed on a second side of the substrate core (e.g., the second core surface 320) exposed by the removal of the carrier 210 and the pedestal 220. (Block 1160). In some examples, the second dielectric material 610 is disposed to serve as a dielectric layer within the build-up region 128 on the second side of the substrate core 130. In some examples, the second dielectric material 610 is the same material as the first dielectric material 410. In other examples, the second dielectric material 610 is different than the first dielectric material 410.

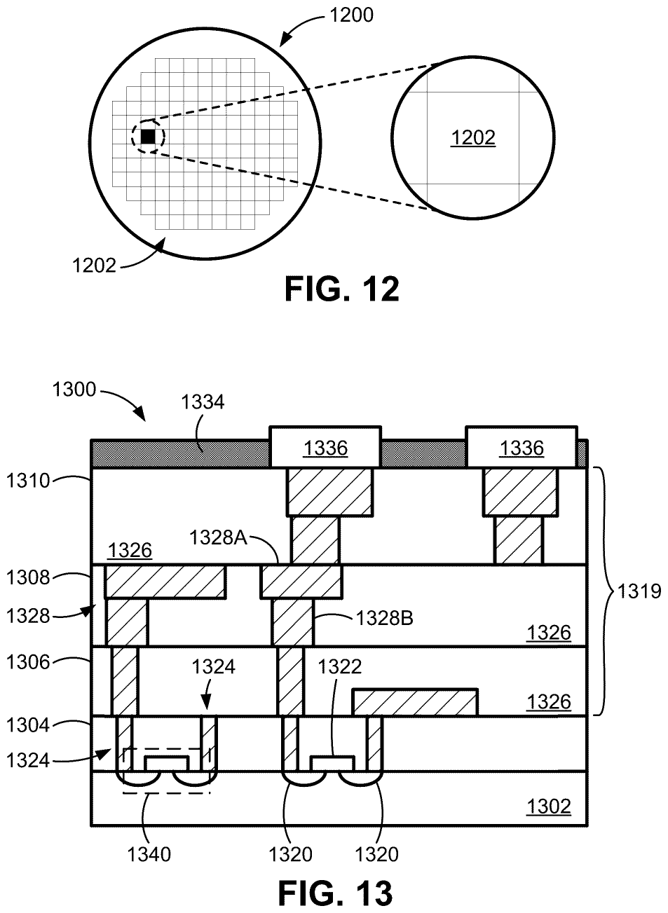

The example IC package 100 disclosed herein may be included in any suitable electronic component. FIGS. 12-15 illustrate various examples of apparatus that may include or be included in the IC package 100 disclosed herein.

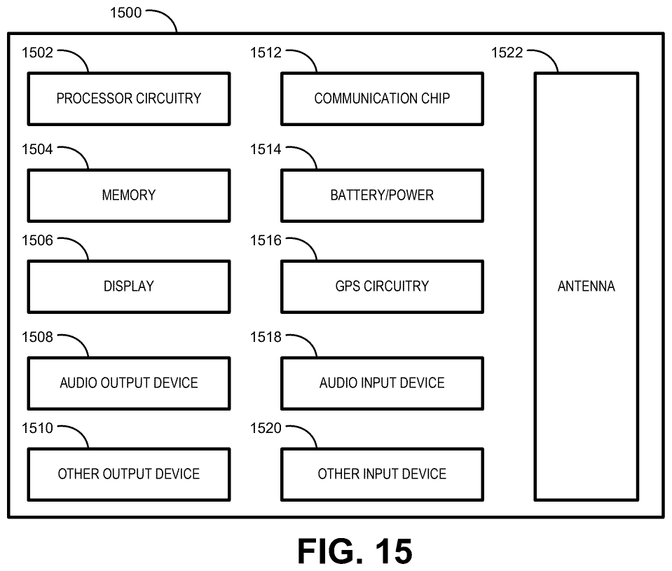

FIG. 12 is a top view of a wafer 1200 and dies 1202 that may be included in the IC package 100 of FIG. 1 (e.g., as any suitable ones of the dies 106, 108). The wafer 1200 may be composed of semiconductor material and may include one or more dies 1202 having circuitry. Each of the dies 1202 may be a repeating unit of a semiconductor product. After the fabrication of the semiconductor product is complete, the wafer 1200 may undergo a singulation process in which the dies 1202 are separated from one another to provide discrete “chips.” The die 1202 may include one or more transistors (e.g., some of the transistors 1340 of FIG. 13, discussed below), supporting circuitry to route electrical signals to the transistors, passive components (e.g., traces, resistors, capacitors, inductors, and/or other circuitry), and/or any other components. In some examples, the die 1202 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 1202. For example, a memory array formed by multiple memory circuits may be formed on a same die 1202 as programmable circuitry (e.g., the processor circuitry 1502 of FIG. 15) or other logic circuitry. Such memory may store information for use by the programmable circuitry. The example IC package 100 disclosed herein may be manufactured using a die-to-wafer assembly technique in which some dies are attached to a wafer 1200 that include others of the dies, and the wafer 1200 is subsequently singulated.

FIG. 13 is a cross-sectional side view of an IC device 1300 that may be included in the IC package 100 of FIG. 1 (e.g., as any suitable ones of the dies 106, 108). One or more of the IC devices 1300 may be included in one or more dies 1202 (FIG. 12). The IC device 1300 may be formed on a die substrate 1302 (e.g., the wafer 1200 of FIG. 12) and may be included in a die (e.g., the die 1202 of FIG. 12). The die substrate 1302 may be a semiconductor substrate composed of semiconductor material systems including, for example, n-type or p-type materials systems (or a combination of both). The die substrate 1302 may include, for example, a crystalline substrate formed using a bulk silicon or a silicon-on-insulator (SOI) substructure. In some examples, the die substrate 1302 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1302. Although a few examples of materials from which the die substrate 1302 may be formed are described here, any material that may serve as a foundation for an IC device 1300 may be used. The die substrate 1302 may be part of a singulated die (e.g., the dies 1202 of FIG. 12) or a wafer (e.g., the wafer 1200 of FIG. 12).

The IC device 1300 may include one or more device layers 1304 disposed on or above the die substrate 1302. The device layer 1304 may include features of one or more transistors 1340 (e.g., metal oxide semiconductor field-effect transistors (MOSFETs)) formed on the die substrate 1302. The device layer 1304 may include, for example, one or more source and/or drain (S/D) regions 1320, a gate 1322 to control current flow between the S/D regions 1320, and one or more S/D contacts 1324 to route electrical signals to/from the S/D regions 1320. The transistors 1340 may include additional features not depicted for the sake of clarity, such as device isolation regions, gate contacts, and the like. The transistors 1340 are not limited to the type and configuration depicted in FIG. 13 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1340 may include a gate 1322 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1340 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1340 along the source-channel-drain direction, the gate electrode may consist of a U-shaped structure that includes a bottom portion substantially parallel to the surface of the die substrate 1302 and two sidewall portions that are substantially perpendicular to the top surface of the die substrate 1302. In other examples, at least one of the metal layers that form the gate electrode may simply be a planar layer that is substantially parallel to the top surface of the die substrate 1302 and does not include sidewall portions substantially perpendicular to the top surface of the die substrate 1302. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 1320 may be formed within the die substrate 1302 adjacent to the gate 1322 of each transistor 1340. The S/D regions 1320 may be formed using an implantation/diffusion process or an etching/deposition process, for example. In the former process, dopants such as boron, aluminum, antimony, phosphorous, or arsenic may be ion-implanted into the die substrate 1302 to form the S/D regions 1320. An annealing process that activates the dopants and causes them to diffuse farther into the die substrate 1302 may follow the ion-implantation process. In the latter process, the die substrate 1302 may first be etched to form recesses at the locations of the S/D regions 1320. An epitaxial deposition process may then be carried out to fill the recesses with material that is used to fabricate the S/D regions 1320. In some implementations, the S/D regions 1320 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1320 may be formed using one or more alternate semiconductor materials such as germanium or a group III-V material or alloy. In further examples, one or more layers of metal and/or metal alloys may be used to form the S/D regions 1320.

Electrical signals, such as power and/or input/output (I/O) signals, may be routed to and/or from the devices (e.g., transistors 1340) of the device layer 1304 through one or more interconnect layers disposed on the device layer 1304 (illustrated in FIG. 13 as interconnect layers 1306-1310).

For example, electrically conductive features of the device layer 1304 (e.g., the gate 1322 and the S/D contacts 1324) may be electrically coupled with the interconnect structures 1328 of the interconnect layers 1306-1310. The one or more interconnect layers 1306-1310 may form a metallization stack (also referred to as an “ILD stack”) 1319 of the IC device 1300.

The interconnect structures 1328 may be arranged within the interconnect layers 1306-1310 to route electrical signals according to a wide variety of designs (in particular, the arrangement is not limited to the particular configuration of interconnect structures 1328 depicted in FIG. 13). Although a particular number of interconnect layers 1306-1310 is depicted in FIG. 13, examples of the present disclosure include IC devices having more or fewer interconnect layers than depicted.

In some examples, the interconnect structures 1328 may include lines 1328a and/or vias 1328b filled with an electrically conductive material such as a metal. The lines 1328a may be arranged to route electrical signals in a direction of a plane that is substantially parallel with a surface of the die substrate 1302 upon which the device layer 1304 is formed. For example, the lines 1328a may route electrical signals in a direction in and out of the page from the perspective of FIG. 13. The vias 1328b may be arranged to route electrical signals in a direction of a plane that is substantially perpendicular to the surface of the die substrate 1302 upon which the device layer 1304 is formed. In some examples, the vias 1328b may electrically couple lines 1328a of different interconnect layers 1306-1310 together.

The interconnect layers 1306-1310 may include a dielectric material 1326 disposed between the interconnect structures 1328, as shown in FIG. 13. In some examples, the dielectric material 1326 disposed between the interconnect structures 1328 in different ones of the interconnect layers 1306-1310 may have different compositions; in other examples, the composition of the dielectric material 1326 between different interconnect layers 1306-1310 may be the same.

A first interconnect layer 1306 (referred to as Metal 1 or “M1”) may be formed directly on the device layer 1304. In some examples, the first interconnect layer 1306 may include lines 1328a and/or vias 1328b, as shown. The lines 1328a of the first interconnect layer 1306 may be coupled with contacts (e.g., the S/D contacts 1324) of the device layer 1304.

A second interconnect layer 1308 (referred to as Metal 2 or “M2”) may be formed directly on the first interconnect layer 1306. In some examples, the second interconnect layer 1308 may include vias 1328b to couple the lines 1328a of the second interconnect layer 1308 with the lines 1328a of the first interconnect layer 1306. Although the lines 1328a and the vias 1328b are structurally delineated with a line within each interconnect layer (e.g., within the second interconnect layer 1308) for the sake of clarity, the lines 1328a and the vias 1328b may be structurally and/or materially contiguous (e.g., simultaneously filled during a dual-damascene process) in some examples.

A third interconnect layer 1310 (referred to as Metal 3 or “M3”) (and additional interconnect layers, as desired) may be formed in succession on the second interconnect layer 1308 according to similar techniques and configurations described in connection with the second interconnect layer 1308 or the first interconnect layer 1306. In some examples, the interconnect layers that are “higher up” in the metallization stack 1319 in the IC device 1300 (i.e., further away from the device layer 1304) may be thicker.

The IC device 1300 may include a solder resist material 1334 (e.g., polyimide or similar material) and one or more conductive contacts 1336 formed on the interconnect layers 1306-1310. In FIG. 13, the conductive contacts 1336 are illustrated as taking the form of bond pads. The conductive contacts 1336 may be electrically coupled with the interconnect structures 1328 and configured to route the electrical signals of the transistor(s) 1340 to other external devices. For example, solder bonds may be formed on the one or more conductive contacts 1336 to mechanically and/or electrically couple a chip including the IC device 1300 with another component (e.g., a circuit board). The IC device 1300 may include additional or alternate structures to route the electrical signals from the interconnect layers 1306-1310; for example, the conductive contacts 1336 may include other analogous features (e.g., posts) that route the electrical signals to external components.

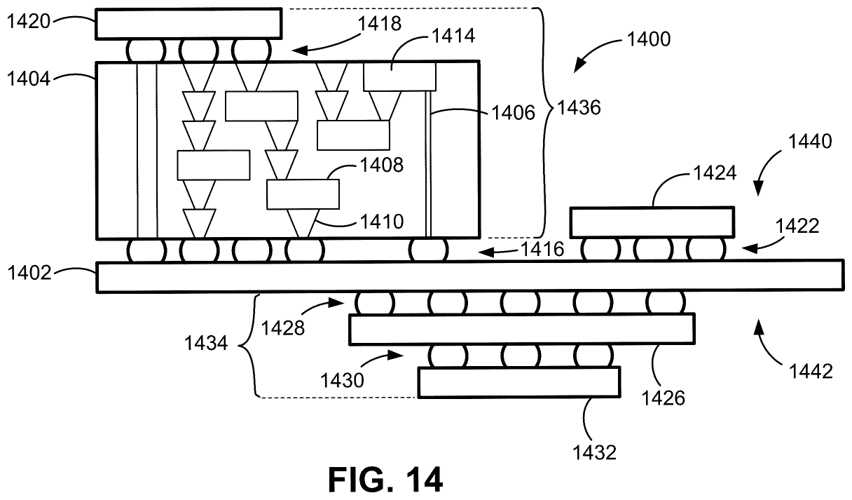

FIG. 14 is a cross-sectional side view of an IC device assembly 1400 that may include the IC package 100 disclosed herein. In some examples, the IC device assembly corresponds to the IC package 100. The IC device assembly 1400 includes a number of components disposed on a circuit board 1402 (which may be, for example, a motherboard). The IC device assembly 1400 includes components disposed on a first face 1440 of the circuit board 1402 and an opposing second face 1442 of the circuit board 1402; generally, components may be disposed on one or both faces 1440 and 1442. Any of the IC packages discussed below with reference to the IC device assembly 1400 may take the form of the example IC package 100 of FIG. 1.

In some examples, the circuit board 1402 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1402. In other examples, the circuit board 1402 may be a non-PCB substrate.

The IC device assembly 1400 illustrated in FIG. 14 includes a package-on-interposer structure 1436 coupled to the first face 1440 of the circuit board 1402 by coupling components 1416. The coupling components 1416 may electrically and mechanically couple the package-on-interposer structure 1436 to the circuit board 1402, and may include solder balls (as shown in FIG. 14), male and female portions of a socket, an adhesive, an underfill material, and/or any other suitable electrical and/or mechanical coupling structure.

The package-on-interposer structure 1436 may include an IC package 1420 coupled to an interposer 1404 by coupling components 1418. The coupling components 1418 may take any suitable form for the application, such as the forms discussed above with reference to the coupling components 1416. Although a single IC package 1420 is shown in FIG. 14, multiple IC packages may be coupled to the interposer 1404; indeed, additional interposers may be coupled to the interposer 1404. The interposer 1404 may provide an intervening substrate used to bridge the circuit board 1402 and the IC package 1420. The IC package 1420 may be or include, for example, a die (the die 1202 of FIG. 12), an IC device (e.g., the IC device 1300 of FIG. 13), or any other suitable component. Generally, the interposer 1404 may spread a connection to a wider pitch or reroute a connection to a different connection.

For example, the interposer 1404 may couple the IC package 1420 (e.g., a die) to a set of BGA conductive contacts of the coupling components 1416 for coupling to the circuit board 1402. In the example illustrated in FIG. 14, the IC package 1420 and the circuit board 1402 are attached to opposing sides of the interposer 1404; in other examples, the IC package 1420 and the circuit board 1402 may be attached to a same side of the interposer 1404. In some examples, three or more components may be interconnected by way of the interposer 1404.

In some examples, the interposer 1404 may be formed as a PCB, including multiple metal layers separated from one another by layers of dielectric material and interconnected by electrically conductive vias. In some examples, the interposer 1404 may be formed of an epoxy resin, a fiberglass-reinforced epoxy resin, an epoxy resin with inorganic fillers, a ceramic material, or a polymer material such as polyimide. In some examples, the interposer 1404 may be formed of alternate rigid or flexible materials that may include the same materials described above for use in a semiconductor substrate, such as silicon, germanium, and other group III-V and group IV materials. The interposer 1404 may include metal interconnects 1408 and vias 1410, including but not limited to through-silicon vias (TSVs) 1406. The interposer 1404 may further include embedded devices 1414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1404. The package-on-interposer structure 1436 may take the form of any of the package-on-interposer structures known in the art.

The IC device assembly 1400 may include an IC package 1424 coupled to the first face 1440 of the circuit board 1402 by coupling components 1422. The coupling components 1422 may take the form of any of the examples discussed above with reference to the coupling components 1416, and the IC package 1424 may take the form of any of the examples discussed above with reference to the IC package 1420.

The IC device assembly 1400 illustrated in FIG. 14 includes a package-on-package structure 1434 coupled to the second face 1442 of the circuit board 1402 by coupling components 1428. The package-on-package structure 1434 may include a first IC package 1426 and a second IC package 1432 coupled together by coupling components 1430 such that the first IC package 1426 is disposed between the circuit board 1402 and the second IC package 1432. The coupling components 1428, 1430 may take the form of any of the examples of the coupling components 1416 discussed above, and the IC packages 1426, 1432 may take the form of any of the examples of the IC package 1420 discussed above. The package-on-package structure 1434 may be configured in accordance with any of the package-on-package structures known in the art.

FIG. 15 is a block diagram of an example electrical device 1500 that may include one or more of the example IC package 100. For example, any suitable ones of the components of the electrical device 1500 may include one or more of the device assemblies 1400, IC devices 1300, or dies 1202 disclosed herein, and may be arranged in the example IC package 100. A number of components are illustrated in FIG. 15 as included in the electrical device 1500, but any one or more of these components may be omitted or duplicated, as suitable for the application. In some examples, some or all of the components included in the electrical device 1500 may be attached to one or more motherboards. In some examples, some or all of these components are fabricated onto a single system-on-a-chip (SoC) die.

Additionally, in various examples, the electrical device 1500 may not include one or more of the components illustrated in FIG. 15, but the electrical device 1500 may include interface circuitry for coupling to the one or more components. For example, the electrical device 1500 may not include a display 1506, but may include display interface circuitry (e.g., a connector and driver circuitry) to which a display 1506 may be coupled. In another set of examples, the electrical device 1500 may not include an audio input device 1518 (e.g., microphone) or an audio output device 1508 (e.g., a speaker, a headset, earbuds, etc.), but may include audio input or output device interface circuitry (e.g., connectors and supporting circuitry) to which an audio input device 1518 or audio output device 1508 may be coupled.

The electrical device 1500 may include programmable circuitry 1502 (e.g., one or more processing devices). The programmable circuitry 1502 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1500 may include a memory 1504, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1504 may include memory that shares a die with the programmable circuitry 1502. This memory may be used as cache memory and may include embedded dynamic random access memory (eDRAM) or spin transfer torque magnetic random access memory (STT-MRAM).

In some examples, the electrical device 1500 may include a communication chip 1512 (e.g., one or more communication chips). For example, the communication chip 1512 may be configured for managing wireless communications for the transfer of data to and from the electrical device 1500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1512 may operate in accordance with other wireless protocols in other examples. The electrical device 1500 may include an antenna 1522 to facilitate wireless communications and/or to receive other wireless communications (such as AM or FM radio transmissions).

In some examples, the communication chip 1512 may manage wired communications, such as electrical, optical, or any other suitable communication protocols (e.g., the Ethernet). As noted above, the communication chip 1512 may include multiple communication chips. For instance, a first communication chip 1512 may be dedicated to shorter-range wireless communications such as Wi-Fi or Bluetooth, and a second communication chip 1512 may be dedicated to longer-range wireless communications such as global positioning system (GPS), EDGE, GPRS, CDMA, WiMAX, LTE, EV-DO, or others. In some examples, a first communication chip 1512 may be dedicated to wireless communications, and a second communication chip 1512 may be dedicated to wired communications.

The electrical device 1500 may include battery/power circuitry 1514. The battery/power circuitry 1514 may include one or more energy storage devices (e.g., batteries or capacitors) and/or circuitry for coupling components of the electrical device 1500 to an energy source separate from the electrical device 1500 (e.g., AC line power).

The electrical device 1500 may include a display 1506 (or corresponding interface circuitry, as discussed above). The display 1506 may include any visual indicators, such as a heads-up display, a computer monitor, a projector, a touchscreen display, a liquid crystal display (LCD), a light-emitting diode display, or a flat panel display.

The electrical device 1500 may include an audio output device 1508 (or corresponding interface circuitry, as discussed above). The audio output device 1508 may include any device that generates an audible indicator, such as speakers, headsets, or earbuds.

The electrical device 1500 may include an audio input device 1518 (or corresponding interface circuitry, as discussed above). The audio input device 1518 may include any device that generates a signal representative of a sound, such as microphones, microphone arrays, or digital instruments (e.g., instruments having a musical instrument digital interface (MIDI) output).

The electrical device 1500 may include GPS circuitry 1516. The GPS circuitry 1516 may be in communication with a satellite-based system and may receive a location of the electrical device 1500, as known in the art.

The electrical device 1500 may include any other output device 1510 (or corresponding interface circuitry, as discussed above). Examples of the other output device 1510 may include an audio codec, a video codec, a printer, a wired or wireless transmitter for providing information to other devices, or an additional storage device.

The electrical device 1500 may include any other input device 1520 (or corresponding interface circuitry, as discussed above). Examples of the other input device 1520 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1500 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1500 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that improve semiconductor device alignment in an integrated circuit package. Disclosed systems, apparatus, articles of manufacture, and methods provide reduced or eliminated misalignment of semiconductor devices within an IC package to improve performance and consistency across the manufacturing of IC packages.

Example methods, apparatus, systems, and articles of manufacture to facilitate semiconductor device alignment in an integrated circuit package are disclosed herein. Further examples and combinations thereof include the following:

Example 1 includes a package substrate comprising a core having a first surface along a first plane and a second surface along a second plane, the second surface opposite the first surface, a semiconductor device disposed within an opening in the core, the semiconductor device having a third surface along a third plane and a fourth surface along a fourth plane, the third surface opposite the fourth surface, the third plane substantially parallel to the first plane, a first dielectric material disposed on the first surface of the core, the first dielectric material extends into the opening to fill a first gap between a wall of the opening and a lateral surface of the semiconductor device, and a second dielectric material disposed on the second surface of the core, the second dielectric material extends into the opening to fill a second gap between the second plane and the fourth plane.

Example 2 includes the package substrate of example 1, wherein the semiconductor device includes a deep trench capacitor.

Example 3 includes the package substrate of example 1, wherein the first dielectric material is in contact with the second dielectric material.

Example 4 includes the package substrate of example 1, wherein a first portion of the first dielectric material extends a first distance between the first and second planes, and a second portion of the first dielectric material extends a second distance between the first and second planes, the second distance less than the first distance.

Example 5 includes the package substrate of example 4, wherein the first portion of the first dielectric material extends along the wall of the opening, and the second portion of the first dielectric material extends along the lateral surface of the semiconductor device.

Example 6 includes the package substrate of example 5, wherein the first distance extends from the first plane to the second plane, and the second distance extends from the first plane to the fourth plane.

Example 7 includes the package substrate of example 1, wherein the fourth plane is between the first and second planes, and the first dielectric material extends into the opening a distance beyond the fourth plane.

Example 8 includes the package substrate of example 7, wherein the first dielectric material has a first lateral thickness between the first plane and the fourth plane and a second lateral thickness between the second plane and the fourth plane, the second lateral thickness equal to or greater than the first lateral thickness.

Example 9 includes the package substrate of example 1, wherein the first dielectric material and the second dielectric material are a same material.

Example 10 includes the package substrate of example 1, wherein the first dielectric material and the second dielectric material are different.

Example 11 includes an integrated circuit package comprising a core having a first thickness defined by first and second surfaces of the core, a deep trench capacitor disposed within an opening in the core, the deep trench capacitor having a second thickness defined by third and fourth surfaces of the deep trench capacitor, the second thickness less than the first thickness, the third surface of the deep trench capacitor substantially flush with the first surface of the core, and a first dielectric material disposed on the first surface of the core and the third surface of the deep trench capacitor, the first dielectric material extends into the opening along a lateral surface of the deep trench capacitor, the first dielectric material to mechanically couple the deep trench capacitor to the core.

Example 12 includes the integrated circuit package of example 11, further including a second dielectric material disposed on the second surface of the core and the fourth surface of the deep trench capacitor.

Example 13 includes the integrated circuit package of example 12, wherein the first dielectric material is in contact with the second dielectric material.

Example 14 includes the integrated circuit package of example

13, wherein the first dielectric material contacts the second dielectric material along an interface, a first portion of the interface extends in a first direction transverse to the first and second surfaces of the core.

Example 15 includes the integrated circuit package of example 14, wherein a second portion of the interface extends in a second direction substantially coplanar with the fourth surface of the deep trench capacitor.

Example 16 includes a method comprising positioning a core on a carrier, the carrier including a pedestal extending into an opening in the core, the core having a first surface facing away from the carrier and a second surface facing towards the carrier, positioning a semiconductor device on the pedestal, the semiconductor device having a third surface facing away from the pedestal and a fourth surface facing towards the pedestal, the pedestal dimensioned to place the third surface of the semiconductor device in substantial coplanar alignment with the first surface of the core, depositing a first dielectric material on the first surface of the core and the third surface of the semiconductor device, the first dielectric material extends into the opening to at least partially cover lateral surfaces of the semiconductor device and to contact the pedestal, and removing the carrier and the pedestal, the first dielectric material to retain the semiconductor device in place relative to the core after the removing of the carrier and the pedestal.

Example 17 includes the method of example 16, further including depositing a second dielectric material on the second surface of the core, the second dielectric material extends into a gap in the opening created by the removing of the pedestal from within the opening.

Example 18 includes the method of example 16, further including providing a debonding film between the carrier and the core and between the pedestal and the semiconductor device, the debonding film to facilitate the removing of the carrier and the pedestal.

Example 19 includes the method of example 18, further including providing the debonding film on surfaces of at least one of the carrier or the pedestal exposed within the opening and spaced apart from the semiconductor device.

Example 20 includes the method of example 16, wherein the pedestal is an integral extension of the carrier.

Example 21 includes the method of example 16, wherein the positioning of the semiconductor device on the pedestal is completed before the positioning of the core on the carrier.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. A package substrate comprising:
a core having a first surface along a first plane and a second surface along a second plane, the second surface opposite the first surface;
a semiconductor device disposed within an opening in the core, the semiconductor device having a third surface along a third plane and a fourth surface along a fourth plane, the third surface opposite the fourth surface, the third plane substantially parallel to the first plane;
a first dielectric material disposed on the first surface of the core, the first dielectric material extends into the opening to fill a first gap between a wall of the opening and a lateral surface of the semiconductor device; and
a second dielectric material disposed on the second surface of the core, the second dielectric material extends into the opening to fill a second gap between the second plane and the fourth plane.

2. The package substrate of claim 1, wherein the semiconductor device includes a deep trench capacitor.

3. The package substrate of claim 1, wherein the first dielectric material is in contact with the second dielectric material.

4. The package substrate of claim 1, wherein a first portion of the first dielectric material extends a first distance between the first and second planes, and a second portion of the first dielectric material extends a second distance between the first and second planes, the second distance less than the first distance.

5. The package substrate of claim 4, wherein the first portion of the first dielectric material extends along the wall of the opening, and the second portion of the first dielectric material extends along the lateral surface of the semiconductor device.

6. The package substrate of claim 5, wherein the first distance extends from the first plane to the second plane, and the second distance extends from the first plane to the fourth plane.

7. The package substrate of claim 1, wherein the fourth plane is between the first and second planes, and the first dielectric material extends into the opening a distance beyond the fourth plane.

8. The package substrate of claim 7, wherein the first dielectric material has a first lateral thickness between the first plane and the fourth plane and a second lateral thickness between the second plane and the fourth plane, the second lateral thickness equal to or greater than the first lateral thickness.

9. The package substrate of claim 1, wherein the first dielectric material and the second dielectric material are a same material.

10. The package substrate of claim 1, wherein the first dielectric material and the second dielectric material are different.

11. An integrated circuit package comprising:
a core having a first thickness defined by first and second surfaces of the core;
a deep trench capacitor disposed within an opening in the core, the deep trench capacitor having a second thickness defined by third and fourth surfaces of the deep trench capacitor, the second thickness less than the first thickness, the third surface of the deep trench capacitor substantially flush with the first surface of the core; and
a first dielectric material disposed on the first surface of the core and the third surface of the deep trench capacitor, the first dielectric material extends into the opening along a lateral surface of the deep trench capacitor, the first dielectric material to mechanically couple the deep trench capacitor to the core.

12. The integrated circuit package of claim 11, further including a second dielectric material disposed on the second surface of the core and the fourth surface of the deep trench capacitor.

13. The integrated circuit package of claim 12, wherein the first dielectric material is in contact with the second dielectric material.

14. The integrated circuit package of claim 13, wherein the first dielectric material contacts the second dielectric material along an interface, a first portion of the interface extends in a first direction transverse to the first and second surfaces of the core.

15. The integrated circuit package of claim 14, wherein a second portion of the interface extends in a second direction substantially coplanar with the fourth surface of the deep trench capacitor.

16. A method comprising:
positioning a core on a carrier, the carrier including a pedestal extending into an opening in the core, the core having a first surface facing away from the carrier and a second surface facing towards the carrier;
positioning a semiconductor device on the pedestal, the semiconductor device having a third surface facing away from the pedestal and a fourth surface facing towards the pedestal, the pedestal dimensioned to place the third surface of the semiconductor device in substantial coplanar alignment with the first surface of the core;
depositing a first dielectric material on the first surface of the core and the third surface of the semiconductor device, the first dielectric material extends into the opening to at least partially cover lateral surfaces of the semiconductor device and to contact the pedestal; and
removing the carrier and the pedestal, the first dielectric material to retain the semiconductor device in place relative to the core after the removing of the carrier and the pedestal.

17. The method of claim 16, further including depositing a second dielectric material on the second surface of the core, the second dielectric material extends into a gap in the opening created by the removing of the pedestal from within the opening.

18. The method of claim 16, further including providing a debonding film between the carrier and the core and between the pedestal and the semiconductor device, the debonding film to facilitate the removing of the carrier and the pedestal.

19. The method of claim 18, further including providing the debonding film on surfaces of at least one of the carrier or the pedestal exposed within the opening and spaced apart from the semiconductor device.

20. The method of claim 16, wherein the pedestal is an integral extension of the carrier.

21. (canceled)
